(19) United States
(12) Patent Application Publication
(10) Pub. No.: US 2025/0280711 A1
(43) Pub. Date: Sep. 4, 2025

(54) Display Device

(71) Applicant: LG Display Co., Ltd., Seoul (KR)

(72) Inventor: Howon Choi, Paju-si (KR)

(21) Appl. No.: 19/058,776

(22) Filed: Feb. 20, 2025

(30) Foreign Application Priority Data
Feb. 29, 2024 (KR) 10-2024-0030123

(51) Int. Cl. H10K 59/80; H10K 59/122; H10K 59/124; H10K 59/131; H10K 59/38

(52) U.S. Cl. CPC H10K 59/875; H10K 59/122; H10K 59/124; H10K 59/131; H10K 59/38

(57) ABSTRACT

The present disclosure provides a display device that includes a substrate on which a plurality of subpixels are disposed, a first insulating layer disposed over the substrate and including at least one depressed portion between the plurality of subpixels, a second insulating layer disposed on the first insulating layer and including at least one opening corresponding to the depressed portion, and a first electrode disposed on the second insulating layer, and is capable of improving light extraction efficiency and eliminating or reducing light leakage between subpixels.

### CROSS-REFERENCE TO RELATED APPLICATION

This application claims the priority benefit of Republic of Korea Patent Application No. 10-2024-0030123, filed on Feb. 29, 2024, which is hereby incorporated by reference in its entirety.

### TECHNICAL FIELD

The present disclosure relates to electronic devices, and more specifically, to display devices.

### BACKGROUND

With the advent of information society, there have been growing needs display devices for displaying images. To meet such needs, various types of display devices, such as a liquid crystal display (LCD) device, an organic light emitting display (OLED) device, an inorganic light emitting display (iLED) device, a micro light emitting display (micro LED) device, a mini light emitting displays (mini LED) device, a quantum dot light emitting display (QLED) device, and the like, have been developed and widely used.

Display devices can have a structure of enabling light emitted from light emitting elements to move out of the display devices for displaying images. The display devices have suffered from a problem in which luminance of the display devices is reduced due to a situation where light emitted from light emitting elements is trapped inside of the display devices without moving out, and the like. Challenges can arise in improving the luminance of display devices.

Display devices may include color filters for restricting specific wavelengths of light or shifting a wavelength band of light in subpixels. Light leakage occurring between some subpixels can cause the image quality of display devices to be reduced. There is therefore a need for eliminating or reducing the light leakage between subpixels.

### SUMMARY

To achieve the foregoing, one or more aspects of the present disclosure may provide a display device capable of improving light extraction efficiency.

One or more embodiments of the present disclosure may provide a display device capable of eliminating or reducing light leakage between subpixels.

One or more embodiments of the present disclosure may provide a display device capable of improving image quality by improving light extraction efficiency and eliminating or reducing light leakage between subpixels.

One or more embodiments of the present disclosure may provide a display device capable of being driven with low power by improving light extraction efficiency and eliminating or reducing light leakage between subpixels.

According to one or more example embodiments of the present disclosure, a display device can be provided that includes a substrate on which a plurality of subpixels are disposed, a first insulating layer disposed over the substrate and including at least one depressed portion between the plurality of subpixels, a second insulating layer disposed on the first insulating layer and including at least one opening corresponding to the at least one depressed portion, and a first electrode disposed on the second insulating layer.

According to one or more example embodiments of the present disclosure, a display device can be provided that includes a substrate, a first insulating layer disposed over the substrate, and including a depressed portion including a flat portion, an inclined portion extending from the flat portion, and a peripheral portion extending from the inclined portion, a second insulating layer disposed on the first insulating layer and disposed in an area corresponding to the peripheral portion of the depressed portion, a first electrode disposed on the second insulating layer, an emission layer disposed on the first electrode and disposed on the depressed portion, and a second electrode disposed on the emission layer.

According to one or more embodiments of the present disclosure, a display device may be provided that includes structures where a depressed portion and an opening are disposed between subpixels, and thereby, is capable of improving light extraction efficiency.

According to one or more embodiments of the present disclosure, a display device may be provided that includes structures where a depressed portion and an opening are disposed between subpixels, and thereby, is capable of eliminating or reducing light leakage between subpixels.

According to one or more embodiments of the present disclosure, a display device may be provided that is capable of improving image quality by improving light extraction efficiency and eliminating or reducing light leakage between subpixels.

According to one or more embodiments of the present disclosure, a display device may be provided that is capable of being driven with low power by improving light extraction efficiency and eliminating or reducing light leakage between subpixels.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates an example system configuration of a display device according to an embodiment of the present disclosure;

FIG. 2 illustrates an example display panel according to an embodiment of the present disclosure;

FIG. 3 is a plan view illustrating example four subpixels disposed in an active area of the display device according to an embodiment of the present disclosure;

FIG. 4 is an example cross-sectional view taken along line A-B of FIG. 3 according to an embodiment of the present disclosure;

FIGS. 5 to 10 are example cross-sectional views taken along line A-B of FIG. 3 according to embodiments of the present disclosure;

FIG. 11 is an example cross-sectional view taken along line C-D of FIG. 3 according to an embodiment of the present disclosure; and

FIG. 12 is an example cross-sectional view taken along line C-D of FIG. 3 according to an embodiment of the present disclosure.

### DETAILED DESCRIPTION

Reference will now be made in detail to embodiments of the present disclosure, examples of which may be illustrated in the accompanying drawings.

In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure. Further, the protected scope of the present disclosure is defined by claims and their equivalents. In the following description, where the detailed description of the relevant known function or configuration may unnecessarily obscure aspects of the present disclosure, a detailed description of such known function or configuration may be omitted. The shapes, sizes, ratios, angles, numbers, and the like, which are illustrated in the drawings to describe various example embodiments of the present disclosure, are merely given by way of example. Therefore, the present disclosure is not limited to the illustrations in the drawings. Where the terms “comprise,” “have,” “include,” “contain,” “constitute,” “make up of,” “formed of,” and the like are used, one or more other elements may be added unless the term, such as “only,” is used. An element described in the singular form is intended to include a plurality of elements, and vice versa, unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

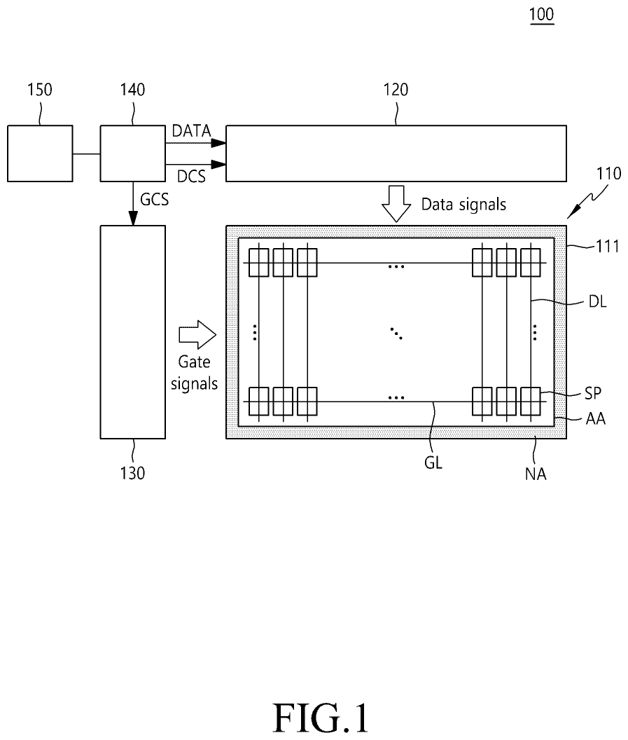

FIG. 1 illustrates an example system configuration of a display device 100 according to an embodiment of the present disclosure. All components of each display device according to all aspects of the present disclosure are operatively coupled and configured.

Referring to FIG. 1, in one or more embodiment, the display device 100 may include a display panel 110 and a display driving circuit, as elements configured to display images. The display driving circuit may be a circuit configured to drive the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include an active area AA allowing an image to be displayed and a non-active area NA disposed outside of the active area AA.

The active area AA may also be referred to as a display area DA, and a plurality of subpixels SP for displaying images may be disposed at the active area AA. The non-active area NA may also be referred to as a non-display area NA and may include a pad area PA, and the like. For example, the pad area PA may be a portion of the non-active area NA disposed in a first direction (e.g., a column direction or a row direction) from the active area AA.

In one or more embodiments, the display panel 110 may be configured to have a very small non-active area NA. Herein, the non-active area NA may also be referred to as “bezel.” For example, the non-active area NA may include a first non-active area disposed outside of the active area AA in a first direction, a second non-active area disposed outside of the active area AA in a second direction, a third non-active area disposed outside of the active area AA in a direction opposite to the first direction, and a fourth non-active area disposed outside of the active area AA in a direction opposite to the second direction. The first non-active area among the first to fourth non-active areas may include a pad area to which at least one driving circuit is connected or bonded. Among the first to fourth non-active areas, the second to fourth non-active areas, which do not include a pad area, may have a very small size compared to the first non-active area.

In another example, the non-active area NA may be bent along a boundary between the active area AA and the non-active area NA at a certain angle to the active area AA, and thereby, be located under the active area AA. In this implementation, when a user views the display device 100 in front thereof, all or most of the non-active area NA may not be visible to the user. But aspects of the present disclosure are not limited thereto.

Various types of signal lines for driving a plurality of subpixels SP may be disposed on the substrate 111 of the display panel 110.

In some embodiments, the display device 100 may be a liquid crystal display device, or the like, or a self-emission display device in which light is emitted from the display panel 110 itself. In an example where the display device 100 is the self-emission display device, each of the plurality of subpixels SP may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In further another example, the display device 100 according to aspects of the present disclosure may be a quantum dot display device in which light emitting elements are implemented using quantum dots, which are self-emission semiconductor crystals.

The structure of each of the plurality of subpixels SP may depend on types of display device 100. For example, in an example where the display device 100 is a self-emission display device including self-emission subpixels SP, each subpixel SP may include a self-emission light emitting element, one or more transistors, and one or more capacitors.

The various types of signal lines may include, for example, a plurality of data lines DL for carrying data signals (which may be referred to as data voltages or image signals), a plurality of gate lines GL for carrying gate signals (which may be referred to as scan signals), and the like.

In one or more embodiments, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column or vertical direction, and the second direction may be the row or horizontal direction. In another example, the first direction may be the row or horizontal direction, and the second direction may be the column or vertical direction. Hereinafter, for convenience of explanation, discussions are provided based on examples where each of the plurality of data lines DL is disposed in the column direction and each of the plurality of gate lines GL is disposed in the row direction, but aspects of the present disclosure are not limited thereto.

The data driving circuit 120 may be a circuit for driving a plurality of data lines DL and can output data signals to the plurality of data lines DL.

The data driving circuit 120 can receive image data DATA in a digital form from the controller 140, and convert the received image data DATA into data signals in an analog form, and output the converted data signals to the plurality of data lines DL.

In some embodiments, the data driving circuit 120 may be connected to the display panel 110 by a tape-automated-bonding (TAB) technology, or connected to a conductive pad such as a bonding pad of the display panel 110 by a chip-on-glass (COG) technology or a chip-on-panel (COP) technology, or connected to the display panel 110 by a chip-on-film (COF) technology. However, embodiments of the present disclosure are not limited thereto.

The data driving circuit 120 may be disposed in, and/or electrically connected to, but not limited to, only one side or edge (e.g., an upper portion or a lower portion) of the display panel 110. In some embodiments, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to outside of the active area AA of the display panel 110, or be disposed in the active area AA of the display panel 110.

The gate driving circuit 130 may be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In some embodiments, the gate driving circuit 130 in the display device 100 may be embedded into the display panel 110 by a gate-in-panel (GIP) technology. In an example where the gate driving circuit 130 is implemented by the gate-in-panel (GIP) technology, the gate driving circuit 130 may be disposed on the substrate 111 of the display panel 110 during the manufacturing process of the display panel 110 or display device 100.

In one embodiment, the gate driving circuit 130 may be disposed in the non-active area NA of the display panel 110.

In another embodiment, the gate driving circuit 130 may be disposed in the active area AA of the display panel 110. In this implementation, for example, the gate driving circuit 130 may be disposed in, and/or electrically connected to, but not limited to, a portion of a first area (e.g., a left area or a right area) of the active area AA of the display panel 110. In another example, the gate driving circuit 130 may be disposed in, and/or electrically connected to, but not limited to, a portion of a first area (e.g., a left area or a right area) and a portion of a second area (e.g., the right area or the left area) of the active area AA of the display panel 110.

Herein, the gate driving circuit 130 embedded in the display panel 110 by the gate-in-panel (GIP) technology may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more embodiments, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be implemented in the form of a touch panel outside of the display panel 110 or be integrated inside of the display panel 110. In the example where the touch sensor is implemented in the form of the touch panel outside of the display panel 110, such a touch sensor may be referred to as an add-on type. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the process of manufacturing the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing configuration or a mutual capacitance sensing configuration.

In the example where the touch sensing circuit performs touch sensing by the self-capacitance sensing configuration, the touch sensing circuit can perform touch sensing based on a capacitance between one or more touch electrodes and an object such as a finger, a pen, and/or the like. According to the self-capacitance sensing configuration, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual capacitance sensing configuration, the touch sensing circuit can perform touch sensing based on a capacitance between touch electrodes. According to the mutual capacitance sensing configuration, a plurality of touch electrodes may be divided into driving touch electrodes and sensing touch electrodes. The touch driving circuit can drive the driving touch electrodes and sense the sensing touch electrodes.

In one or more embodiments, the touch driving circuit and touch controller included in the touch sensing circuit may be implemented in separate devices or in a single device. In one or more embodiments, the touch driving circuit and the data driving circuit may be implemented in separate devices or in a single device.

The display apparatus 100 may further include a power supply circuit configured to supply various types of power to the display driving circuit and/or the touch sensing circuit.

In some embodiments, the display device 100 may be a mobile terminal such as a smart phone, a tablet, or the like, or a monitor, a television (TV), or the like. Such devices may be configured in various types, sizes, and shapes. The display device 100 according to embodiments of the present disclosure are not limited thereto, and may include various types, sizes, and shapes configured to display information or images. The display device 100 according to embodiments of the present disclosure may be applied to mobile devices, video phones, smart watches, watch phones, wearable devices, foldable devices, rollable devices, bendable devices, flexible devices, stretchable devices, curved devices, sliding devices, variable devices, electronic notebooks, e-books, portable multimedia players (PMP), personal digital assistants (PDA), MP3 players, mobile medical devices, desktop PCs, laptop PCs, netbook computers, workstations, navigation devices, car navigation devices, vehicle display devices, vehicle apparatuses, theater apparatuses, theater display devices, televisions, wallpaper devices, signage devices, game devices, notebook computers, monitors, cameras, camcorders, and home appliances, and the like.

In one or more embodiments, the display device 100 may further include an electronic device such as a camera (e.g., an image sensor), a sensor capable of detecting an object, ambient light, and the like. For example, the sensor may be a sensor capable of detecting an object or a human body by receiving light such as infrared light, ultrasonic light, ultraviolet light or the like.

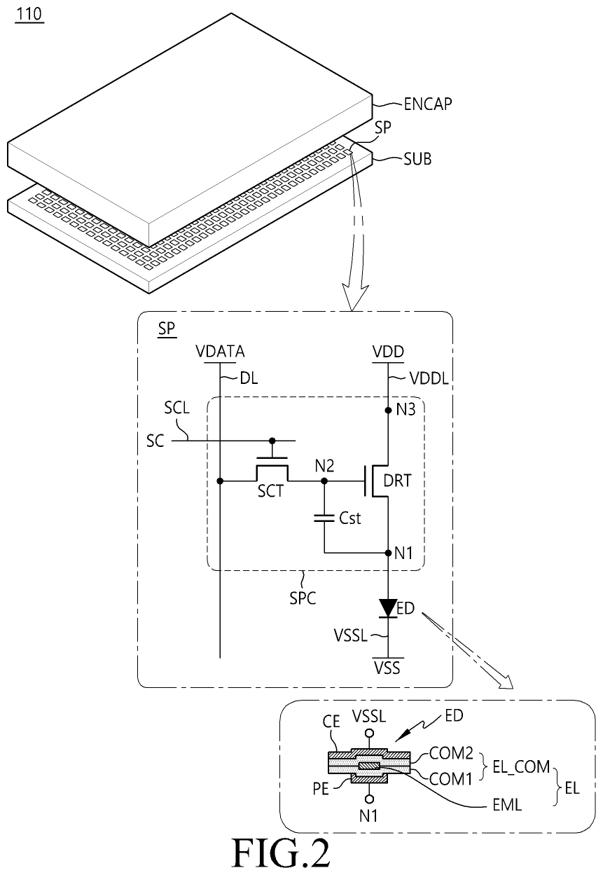

FIG. 2 illustrates an example configuration of the display panel 110 according to embodiments of the present disclosure. In discussions that follow for the configuration of FIG. 2, discussions for features and examples equal, substantially equal, or similar to the features and examples described with reference to FIG. 1 are omitted or briefly described for convenience of description.

Referring to FIG. 2, the display panel 110 may include a substrate SUB on which a plurality of subpixels SP are disposed, and an encapsulation layer ENCAP over the substrate SUB. The encapsulation layer ENCAP may also be referred to as an encapsulation substrate or an encapsulation stack.

Referring to FIG. 2, in an example where the display device 100 is a self-emission display device, each of the plurality of subpixels SP disposed on the substrate SUB may include a light emitting element ED and a subpixel circuit SPC for driving the light emitting element ED.

Referring to FIG. 2, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DRT for driving the light emitting element ED and a scan transistor ST configured to be turned on or turned off according to a scan signal SCT.

The driving transistor DRT can supply a driving current to the light emitting element ED.

The scan transistor SCT may be configured to control an electrical state of a corresponding node in the subpixel circuit SPC or to control the state or operation of the driving transistor DRT.

The at least one capacitor may include a storage capacitor Cst configured to maintain a certain level of voltage during a display frame or a certain period of the display frame.

To drive one or more subpixels SP, at least one data signal VDATA, which is an image signal, and at least one scan signal SC, which is a gate signal, may be applied to the one or more subpixels SP. Further, to drive one or more subpixels SP, a common pixel driving voltage including a first common driving voltage VDD and a second common driving voltage VSS may be applied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode disposed commonly in all or some of a plurality of subpixels SP. For example, the pixel electrode PE may be an anode, and the common electrode CE may be a cathode. In another example, the pixel electrode PE may be a cathode, and the common electrode CE may be an anode. Hereinafter, for convenience of explanation, discussions are provided based on examples where the pixel electrode PE is an anode, and the common electrode CE is a cathode.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

The emission layer EML may be disposed in each subpixel SP, and the common intermediate layer EL_COM may be disposed commonly across all or some of a plurality of subpixels SP.

The emission layer EML may be disposed in each light emitting area, and the common intermediate layer EL_COM may be disposed commonly across all or some of a plurality of light emitting areas and all or some of a plurality of non-light emitting areas.

For example, the first common intermediate layer COM1 may include a hole injection layer (HIL), a hole transfer layer (HTL), and the like. The second common intermediate layer COM2 may include an electron transport layer (ETL), an electron injection layer (EIL), and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

For example, the common electrode CE may be electrically connected to a second common driving voltage line VSSL. A second common driving voltage VSS, which is a type of common pixel driving voltage, may be applied to the common electrode CE through the second common driving voltage line VSSL. The pixel electrode PE may be electrically connected directly or indirectly (via another transistor) to a first node N1 of a corresponding driving transistor DRT of each subpixel SP. Herein, the second common driving voltage VSS may also be referred to as a “base voltage”, and the second common driving voltage line VSSL may also be referred to as a “low power supply voltage line”, a “low voltage line”, or a “base voltage line.

Each light emitting element ED may be configured by overlap of a corresponding pixel electrode PE, a corresponding emission layer in the intermediate layer EL, and a portion of the common electrode CE. A respective light emitting area may be formed by each light emitting element ED. For example, a respective light emitting area of each light emitting element ED may include an area where a corresponding pixel electrode PE, a corresponding emission layer in the intermediate layer EL, and a portion of the common electrode CE overlap with each other.

In some embodiments, each light emitting element ED may be an organic light emitting diode (OLED), an inorganic light emitting diode (iLED), a quantum dot light emitting element (QLED), or the like. In the example where each light emitting element ED is an organic light emitting diode (OLED), the intermediate layer EL of a corresponding light emitting element ED may be a layer including an organic material.

The driving transistor DRT may be a transistor configured to supply a driving current to the light emitting element ED. The driving transistor DRT may be connected between a first common driving voltage line VDDL and the light emitting element ED.

The driving transistor DRT may include a first node N1, a second node N2, and a third node N3. The first node N1 may be electrically connected to the light emitting element ED. A data signal VDATA may be applied to the second node N2. The first common driving voltage VDD may be applied to the third node N3 through the first common driving voltage line VDDL. In the driving transistor DRT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DRT are source, gate, and drain nodes, respectively. However, aspects of the present disclosure are not limited thereto.

The scan transistor SCT included in the subpixel circuit SPC illustrated in FIG. 2 may be a switching transistor for allowing a data signal VDATA, which is an image signal, to be supplied to the second node N2, which is the gate node of the driving transistor DRT.

The scan transistor SCT can be turned on or turned off by a scan signal SC, which is a type of gate signal, carried by a scan line SCL, which is a type of gate line GL, and control an electrical connection between the second node N2 of the driving transistor DRT and a data line DL. The drain electrode or source electrode of the scan transistor SCT may be electrically connected to the data line DL. The source electrode or drain electrode of the scan transistor SCT may be electrically connected to the second node N2 of the driving transistor DRT. The gate electrode of the scan transistor SCT may be electrically connected to the scan line SCL.

The storage capacitor Cst may be electrically connected between the first node N1 and the second node N2 of the driving transistor DRT. The storage capacitor Cst may include a first capacitor electrode electrically connected to the first node N1 of the driving transistor DRT or corresponding to the first node N1 of the driving transistor DRT, and a second capacitor electrode electrically connected to the second node N2 of the driving transistor DRT or corresponding to the second node N2 of the driving transistor DRT.

In some embodiments, the storage capacitor Cst, which may be present between the first node N1 and the second node N2 of the driving transistor DRT, may be an external capacitor intentionally configured or designed to be located outside of the driving transistor DRT, other than internal capacitors, such as parasitic capacitors (e.g., a gate-to-source capacitance Cgs, a gate-to-drain capacitance Cgd, and the like).

Each of the driving transistor DRT and the scan transistor SCT may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2TIC structure”). In some implementations, the subpixel circuit SPC may further include one or more transistors, and/or further include one or more capacitors.

For example, the subpixel circuit SPC may have an 3T1C structure including 3 transistors and 1 capacitor. In another example, the subpixel circuit SPC may have an 6T2C structure including 6 transistors and 2 capacitor. In further another example, the subpixel circuit SPC may have an 7T1C structure including 7 transistors and 1 capacitor. In further another example, the subpixel circuit SPC may have an 8TIC structure including 8 transistors and 1 capacitor.

The types and number of gate signals supplied to a subpixel SP, and/or the types and number of gate lines connected to the subpixel SP may vary depending on a structure of a corresponding subpixel circuit SPC. Further, the types and number of common pixel driving voltages supplied to a subpixel SP may vary depending on a structure of a corresponding subpixel circuit SPC.

Since circuit elements (in particular, a light emitting element ED implemented with an organic light emitting diode including an organic material) included in each subpixel SP are subject to external moisture or oxygen, an encapsulation layer ENCAP may be disposed in the display panel 110 in order to prevent or at least reduce external moisture or oxygen from penetrating into such circuit elements. The encapsulation layer 200 may be disposed in various shapes or configurations to prevent light emitting elements ED from contacting moisture or oxygen. For example, the encapsulation layer 200 may include two or more layers in which organic and inorganic layers are alternately stacked, but aspects of the present disclosure are not limited thereto.

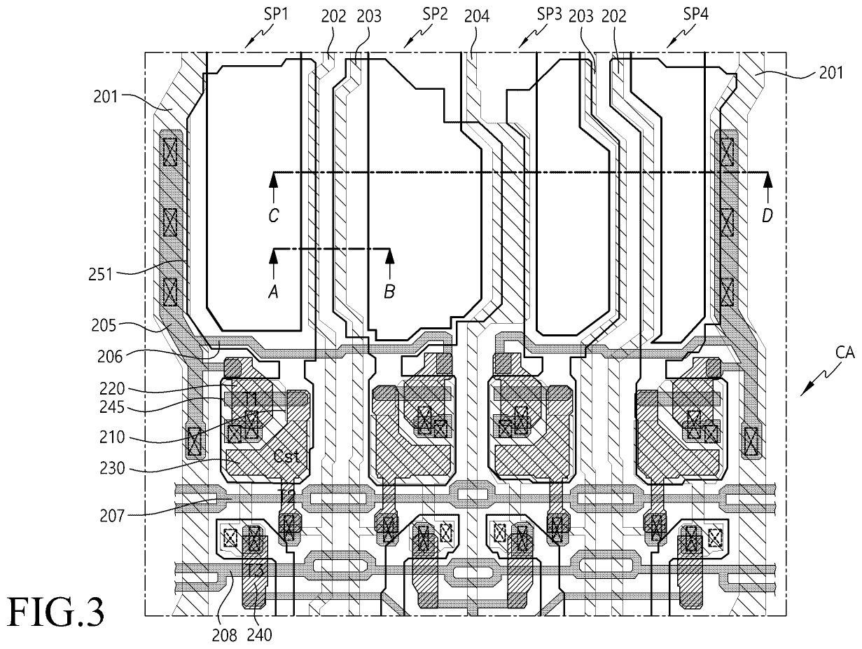

FIG. 3 is a plan view illustrating example four subpixels disposed in the active area AA of the display device 100 according to aspects of the present disclosure. In discussions that follow for the configuration of FIG. 3, discussions for features and examples equal, substantially equal, or similar to the features and examples described with reference to FIGS. 1 and 2 are omitted or briefly described for convenience of description.

Referring to FIG. 3, in one or more embodiments, the display device 100 may include a first subpixel SP1, a second subpixel SP2, a third subpixel SP3, and a fourth subpixel SP4. The first to fourth subpixels (SP1, SP2, SP3, and SP4) may include light emitting areas emitting light of different colors.

For example, the first subpixel SP1 may include a light emitting area emitting red light, the second subpixel SP2 may include a light emitting area emitting white light, the third subpixel SP3 may include a light emitting area emitting blue light, and the fourth subpixel SP4 may include a light emitting area emitting green light.

In one or more embodiments, each of one or more light emitting areas EA disposed in the active area AA of the display device 100 may include a first light emitting area and a second light emitting area.

The first light emitting area may be an area corresponding to an area in which a first electrode, an emission layer, and a second electrode are sequentially stacked and overlap with each other. The first light emitting area may be an area where some of light emitted from the emission layer is directed outside of the display panel 110 or the display device 100 in an open area. The first light emitting area may be referred to as a main light emitting area. The second light emitting area may be an area where some of the light emitted from the emission layer is reflected from an inclined surface and redirected outside of the display panel 110 or the display device 100. For example, the second light emitting area may be an area where some of the light emitted from the emission layer is reflected from a portion of the second electrode disposed on an inclined surface and redirected outside of the display panel 110 or the display device 100. The second light emitting area may be referred to as an auxiliary light emitting area.

The first to fourth subpixels (SP1, SP2, SP3, and SP4) may include respective circuit areas CA for driving light emitting elements disposed in the first to fourth subpixels (SP1, SP2, SP3, and SP4).

Referring to FIG. 3, each of the first to fourth subpixels (SP1, SP2, SP3, and SP4) may include a plurality of transistors (T1, T2, T3) and a storage capacitor Cst disposed in the corresponding circuit area CA. For example, the circuit area CA of each of the first to fourth subpixels (SP1, SP2, SP3, and SP4) may include a first transistor T1, a second transistor T2, a third transistor T3, and a storage capacitor Cst.

For example, a gate electrode 245 and a first active layer 220 included in the first transistor T1, a second active layer 230 included in the second transistor T2, and a third active layer 240 included in the third transistor T3 may be disposed in the circuit area CA. Further, a light shield 210, which may be one of electrodes of the storage capacitor Cst, may be disposed in the circuit area CA.

Referring to FIG. 3, a plurality of signal lines (201, 202, 203, 204, 205, 206, 207, 208) needed to drive the light emitting element may be disposed in the circuit area CA. For example, a first signal line 201 may be a first common driving voltage line VDDL for delivering a first common driving voltage VDD. Second and third signal lines (202 and 203) may be data lines DL for delivering data signals VDATA. A fourth signal line 204 may be a reference voltage line for delivering a reference voltage. Fifth and sixth signal lines (205 and 206) may be connection patterns for distributing the first common driving voltage VDD delivered through the first common driving voltage line VDDL to one or more of the subpixels. A seventh signal line 207 may be a scan line SCL for delivering a scan signal SC. An eighth signal line 208 may be a sensing line for delivering a sensing signal.

One or more of the signal lines (201, 202, 203, 204, 205, 206, 207, and 208) may serve as a source electrode, a drain electrode, or a gate electrode of each of the transistors (T1, T2, and T3).

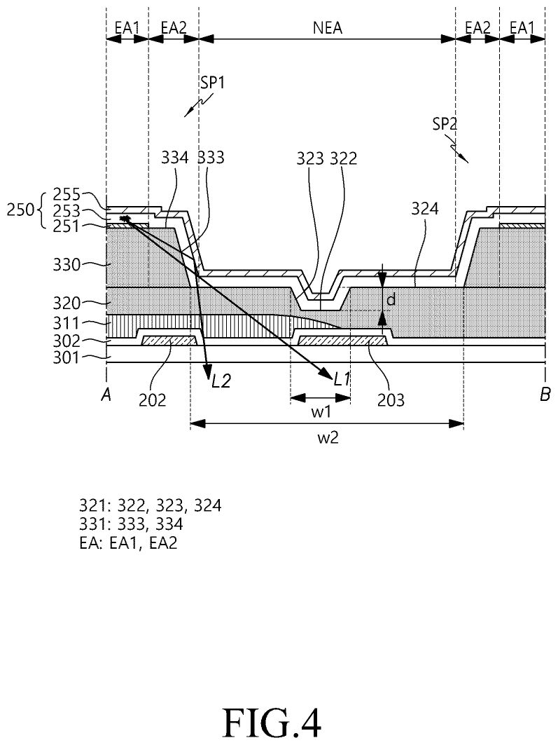

FIG. 4 is an example cross-sectional view taken along line A-B of FIG. 3 according to aspects of the present disclosure. In discussions that follow for the configuration of FIG. 4, discussions for features and examples equal, substantially equal, or similar to the features and examples described with reference to FIGS. 1 to 3 are omitted or briefly described for convenience of description.

Referring to FIG. 4, in one or more embodiments, the display device 100 may include a substrate 301, a first insulating layer 320 including at least one depressed portion 321, a second insulating layer 330 including at least one opening 331, and at least one light emitting element 250.

A plurality of subpixels may be disposed on the substrate 301. For example, the first to fourth subpixels (SP1, SP2, SP3, and SP4) may be disposed on the substrate 301. The first to fourth subpixels (SP1, SP2, SP3, and SP4) may include light emitting areas emitting light of different colors.

The substrate 301 may include an insulating material. The substrate 301 may include glass or plastic. The substrate 301 may have a single layer structure or a multilayer structure. In the example where the substrate 301 has the multilayer structure, the substrate 301 may include a first substrate and a second substrate, and may further include an intermediate layer between the first substrate and the second substrate. The first substrate and the second substrate may include a same material. For example, the first substrate and the second substrate may be polyimide (PI) substrates. The intermediate layer may be an inorganic layer configured with a single layer or multiple layers including silicon nitride (SiNx) or silicon oxide (SiOx). As the intermediate layer is disposed between the first substrate and the second substrate, moisture can be prevented from penetrating into transistors through the first substrate disposed under the transistors, and thereby, the reliability of the display device can be improved.

The second signal line 202 and the third signal line 203 may be disposed on the substrate 301. Each of the second signal line 202 and the third signal line 203 may include a conductive material. For example, the second and third signal lines (202 and 203) may include either a metal such as aluminum (Al), gold (Au), silver (Ag), copper (Cu), tungsten (W), molybdenum (Mo), chromium (Cr), tantalum (Ta), titanium (Ti), or the like, or any one of one or more alloys including one or more thereof, but aspects of the present disclosure are not limited thereto.

A protective layer 302 may be disposed on the second and third signal lines (202 and 203). The protective layer 302 may include an inorganic insulating material. For example, the protective layer 302 may be formed by depositing at least one inorganic insulating material selected among silicon oxide (SiOx), silicon nitride (SiNy), and silicon oxynitride (SiOxNy) on the substrate 301 on which the second and third signal lines (202 and 203) are disposed. The protective layer 302 may have a single layer structure or a multilayer structure. For example, the protective layer 302 may include a single layer including one inorganic insulating material selected among silicon oxide (SiOx), silicon nitride (SiNy), and silicon oxynitride (SiOxNy), or multiple layers including at least one inorganic insulating material selected among silicon oxide (SiOx), silicon nitride (SiNy), and silicon oxynitride (SiOxNy).

A color filter layer including at least one color filter may be disposed on the protective layer 302.

Referring to FIG. 4, the color filter layer may be configured to overlap with one or more of the signal lines (201, 202, 203, and 204) or respective portions of one or more signal lines (201, 202, 203, and/or 204). The color filter layer may include color filters corresponding to colors of light emitted in the first to fourth subpixels (SP1, SP2, SP3, and SP4).

For example, a red (R) color filter 311 may be disposed in the area of the first subpixel SP1 including a light emitting area emitting red (R) light, a blue (B) color filter 312 may be disposed in the area of the third subpixel SP3 including a light emitting area emitting blue (B) light, and a green (G) color filter 313 may be disposed in the area of the fourth subpixel SP4 including the light emitting area emitting green (G) light.

A separate color filter may be not disposed in the area of the second subpixel SP2 including a light emitting area emitting white (W) light. For example, an insulating layer may be disposed in the area of the second subpixel SP2 including the light emitting area emitting white (W) light. For example, the insulating layer, the protective layer 302, and the like disposed or stacked in the area of the second subpixel SP2 may include a transparent material, and thus, a separate color filter may be not disposed in the area of the second subpixel SP2.

A first insulating layer 320 may be disposed on the color filter layer and the protective layer 302.

Due to the signal lines, the color filters, or the like disposed under the first insulating layer 320, the first insulating layer 320 may have a lower portion with a step or have an uneven lower surface. The first insulating layer 320 may be configured with a planarized surface to alleviate a difference in height or thickness caused by the step in the lower portion or the uneven lower surface.

The first insulating layer 320 may also serve to prevent or at least reduce outgassing generated from color filters, which are configured to correspond to subpixels, respectively, from affecting at least one light emitting element 250 disposed on the first insulating layer 320.

The first insulating layer 320 may include at least one depressed portion 321 between adjacent subpixels among the subpixels (SP1, SP2, SP3, and/or SP4).

Referring to FIG. 4, the first insulating layer 320 may include a depressed portion 321 disposed between the first subpixel SP1 and the second subpixel SP2. For example, the first insulating layer 320 may include the depressed portion 321 disposed in a non-light emitting area NFA between the first subpixel SP1 and the second subpixel SP2. The depressed portion 321 may be defined as an area including an area where a portion of the first insulating layer 320 is removed and a surrounding area.

For example, the depressed portion 321 may include a flat portion 322, an inclined portion 323 surrounding the flat portion 322, and a peripheral portion 324 extending from the inclined portion 323.

The flat portion 322 of the depressed portion 321 may be disposed closer to the substrate 301 than the peripheral portion 324 of the depressed portion 32 in a direction perpendicular to a lengthwise direction of the substrate 301.

The flat portion 322 of the depressed portion 321 may be a portion whose surface is parallel to any one surface of the substrate 301. The inclined portion 323 of the depressed portion 321 may be a portion which surrounds the flat portion 322 and in which a surface of the inclined portion 323 has a predetermined angle to any one surface of the substrate 301. The inclined portion 323 of the depressed portion 321 may be configured to extend from the flat portion 322 and surround the flat portion 322. The peripheral portion 324 of the depressed portion 321 may be a portion which extends from the inclined portion 323 and whose surface is parallel to any one surface of the substrate 301. The peripheral portion 324 of the depressed portion 321 may correspond to the upper surface of the first insulating layer 320.

Referring to FIG. 4, a depression included in the depressed portion 321 may have a width representing a distance between the inclined portion 323 disposed adjacent to the first subpixel SP1 and the inclined portion 323 disposed adjacent to the second subpixel SP2. The width of the depression of the depressed portion 321 may increase as the depression of the depressed portion 321 extends away from the substrate 301. For example, a width of the depression at the top of the depressed portion 321 (or a width between inner edges or outer edges of the peripheral portion 324 of the depressed portion 321) may be greater than a width of the flat portion 322 at the bottom of the depressed portion 321. The depressed portion 321 may have a first width w1 being the width of the depression at the top of the depressed portion 321. The first width w1 may be the greatest width of the depression of the depressed portion 321.

Referring to FIG. 4, the depressed portion 321 may be configured to overlap with one or more of the signal lines (201, 202, 203, and 204) or respective portions of one or more signal lines. The depressed portion 321 may be configured to overlap with respective portions of at least two signal lines, for example, the second and third signal lines (202 and 203). The depressed portion 321 including the flat portion 322, the inclined portion 323, and the peripheral portion 324 may be configured to partially overlap with at least one of the second and third signal lines (202 and 203). The flat portion 322 of the depressed portion 321 may be configured to partially overlap with at least one signal line, for example, the third signal line 203. The first width w1 of the depressed portion 321 may be smaller than a width of the third signal line.

Referring to FIG. 4, the depressed portion 321 may be configured to partially overlap with the color filter layer. For example, the depressed portion 321 may be configured to partially overlap with the red (R) color filter 311. For example, the flat portion 322 and the inclined portion 323 of the depressed portion 321 may partially overlap with the red (R) color filter 311.

When the thickness of the first insulating layer 320 is thin, the depressed portion 321 of the first insulating layer 320 may be disposed to slant obliquely toward the area of the second subpixel SP2 emitting white (W) light.

Referring to FIG. 4, the first insulating layer 320 may be disposed between the depressed portion 321 and the color filter layer. For example, the first insulating layer 320 may be disposed continuously without being disconnected between the depressed portion 321 and the red (R) color filter 311. When the depressed portion 321 has a deep depression to such an extent that the red (R) color filter 311 can be exposed, outgassing generated in the color filter may damage a corresponding emission layer, and thereby, the reliability of the display device 100 can be reduced.

The first insulating layer 320 may include an organic insulating material or an inorganic insulating material. For example, the organic insulating material may be at least one material selected among polyimide, benzocyclobutene, acrylate, and photoacrylate, but aspects of the present disclosure are not limited thereto. The inorganic insulating material may be at least one material selected among silicon oxide (SiOx), silicon nitride (SiNy), and silicon oxynitride (SiOxNy), but aspects of the present disclosure are not limited thereto.

A second insulating layer 330 may be disposed on the first insulating layer 320. The second insulating layer 330 may be disposed in areas corresponding to the subpixels (SP1, SP2, SP3, and SP4).

Referring to FIG. 4, the second insulating layer 330 may include at least one opening 331 located between adjacent subpixels among the subpixels (SP1, SP2, SP3, and/or SP4). The second insulating layer 330 may be disposed on the peripheral portion 324 of the first insulating layer 320 so that the opening 331 can be located in an area corresponding to the depressed portion 321 of the first insulating layer 320.

Referring to FIG. 4, the second insulating layer 330 may include the opening 331 located between the first subpixel SP1 and the second subpixel SP2 and located in an area corresponding to the depressed portion 321 of the first insulating layer 320. For example, the opening 331 of the second insulating layer 330 may be located in the non-light emitting area NFA between the first subpixel SP1 and the second subpixel SP2, and be configured to overlap with the depressed portion 321 of the first insulating layer 320 in a direction perpendicular to the lengthwise direction of the substrate 301. The opening 331 of the second insulating layer 330 may be defined an area including an area where a portion of the second insulating layer 330 is removed and a surrounding area.

For example, the opening 331 may include an inclined portion 333 and a peripheral portion 334 extending from the inclined portion 333.

The inclined portion 333 of the opening 331 may be a portion in which the surface of the inclined portion 333 has a predetermined angle to any one surface of the substrate 301. The inclined portion 333 of the opening 331 may be located at the peripheral portion 324 of the depressed portion 321. The peripheral portion 334 of the opening 331 may be a portion which extends from the inclined portion 333 and whose surface is parallel to any one surface of the substrate 301. The peripheral portion 334 of the opening 331 may be a light emitting area.

Referring to FIG. 4, an open portion included in the opening 331 may have a width representing a distance between the inclined portion 333 disposed adjacent to the first subpixel SP1 and the inclined portion 333 disposed adjacent to the second subpixel SP2. The width of the open portion of the opening 331 may increase as the open portion of the opening 331 extends away from the substrate 301. For example, a width of the open portion at the top of the opening 331 may be greater than a width of the open portion at the bottom of the opening 331. The opening 331 may have a second width w2 being the width of the open portion at the bottom of the opening 331. The second width w2 may be the smallest width of the open portion of the opening 331.

The first width w1 of the depressed portion 321 may be smaller than or equal to the second width w2 of the opening 331.

Referring to FIG. 4, the opening 331 may be configured to overlap with one or more of the signal lines (201, 202, 203, and 204). The opening 331 may be configured to overlap with the depressed portion 321 and one or more of the signal lines (201, 202, 203, and 204). For example, the opening 331 may be configured to partially overlap with the depressed portion 321 and the second and third signal lines (202 and 203). For example, the inclined portion 333 and the open portion of the opening 331 may be configured to at least partially overlap with the depressed portion 321 and the second and third signal lines (202 and 203).

Referring to FIG. 4, the opening 331 may be configured to partially overlap with the color filter layer. The opening 331 may be configured to partially overlap with the depressed portion 321 and the color filter layer. For example, the opening 331 may be configured to partially overlap with the depressed portion 321 and the red (R) color filter 311. For example, the inclined portion 333 and the open portion of the opening 331 may be configured to partially overlap with the depressed portion 321 and the red (R) color filter 311.

The second insulating layer 330 may include an organic insulating material or an inorganic insulating material. For example, the organic insulating material may be at least one material selected among polyimide, benzocyclobutene, acrylate, and photoacrylate, but embodiments of the present disclosure are not limited thereto. The inorganic insulating material may be at least one material selected among silicon oxide (SiOx), silicon nitride (SiNy), and silicon oxynitride (SiOxNy), but aspects of the present disclosure are not limited thereto.

The first insulating layer 320 and the second insulating layer 330 may include a same material or different materials.

A light emitting element 250 including a first electrode 251, an emission layer 253, and a second electrode 255 may be disposed on the second insulating layer 330.

The first electrode 251 may be disposed on the second insulating layer 330.

Referring to FIG. 4, the first electrode 251 may be disposed on the peripheral portion 334 of the second insulating layer 330. The first electrode 251 may be disposed on the peripheral portion 334 of the second insulating layer 330 and disposed in an area parallel to any one surface of the substrate 301. The first electrode 251 may be disposed at a higher location from the substrate 301 than the depressed portion 321.

One end or edge of the first electrode 251 may have a regular taper shape, a reverse taper shape, or a vertical shape. In an example where the first electrode 251 is not covered by a bank, the end or edge of the first electrode 251 may have a regular taper shape.

The first electrode 251 may include a conductive material capable of transmitting or semi-transmitting light. For example, the first electrode 251 may include at least one type of transparent conductive oxide, such as indium tin oxide (ITO), indium zinc oxide (IZO), indium tin zinc oxide (ITZO), indium gallium zinc oxide (IGZO), zinc oxide, tin oxide, or the like, or may include a semi-transmissive metal, such as magnesium (Mg), silver (Ag), an alloy of magnesium and silver, or the like. For example, in an example where the first electrode 251 includes a semi-transmissive metal, the thickness of the first electrode 251 may be less than the thickness of the second electrode 255.

However, embodiments of the present disclosure are not limited thereto. For example, any material having high light transmittance and high conductivity may be sufficient for a material to be included in the first electrode 251.

The emission layer 253 may be disposed on the first electrode 251.

Referring to FIG. 4, the emission layer 253 may be configured to extend from a portion of the emission layer 253 disposed on the first electrode 251 to the depressed portion 321. The emission layer 253 may be configured to extend from the portion of the emission layer 253 disposed on the first electrode 251 to the peripheral portion 334 and the inclined portion 333 of the opening 331, and the peripheral portion 324, the inclined portion 323, and the flat portion 322 of the depressed portion 321. The emission layer 253 may be disposed commonly in the subpixels (SP1, SP2, SP3, and SP4).

The second electrode 255 may be disposed on the emission layer 253.

Referring to FIG. 4, the second electrode 255 may be configured to extend from a portion of the second electrode 255 disposed on the emission layer 253 to the depressed portion 321. The second electrode 255 may be configured to extend from the portion of the second electrode 255 disposed on the emission layer 253 to the peripheral portion 334 and the inclined portion 333 of the opening 331, and the peripheral portion 324, the inclined portion 323, and the flat portion 322 of the depressed portion 321. The second electrode 255 may be disposed commonly in the subpixels (SP1, SP2, SP3, and SP4).

The second electrode 255 may include a conductive material capable of reflecting light. For example, the second electrode 255 may include either a metal such as aluminum (Al), magnesium (Mg), gold (Au), silver (Ag), copper (Cu), tungsten (W), molybdenum (Mo), chromium (Cr), tantalum (Ta), titanium (Ti), or the like, or any one of one or more alloys thereof, but aspects of the present disclosure are not limited thereto.

An encapsulation layer (not shown) may be disposed on the second electrode 255 of the light emitting element 250.

The encapsulation layer may be a layer configured to prevent moisture or oxygen from penetrating into the light emitting element 250 disposed under the encapsulation layer. For example, the encapsulation layer may include a single layer or multiple layers.

The encapsulation layer may include, for example, a first encapsulation layer, a second encapsulation layer, and a third encapsulation layer. The first encapsulation layer and the third encapsulation layer may be inorganic layers including an inorganic insulating material, and the second encapsulation layer may be an organic layer including an organic insulating material.

Referring to FIG. 4, the depressed portion 321 of the first insulating layer 320 and the opening 331 of the second insulating layer 330 may be configured to overlap with each other and disposed between the first subpixel SP1 and the second subpixel SP2. As the first insulating layer 320 has the depressed portion 321, the second electrode 255, which is a reflective electrode, can be located in the depressed portion 321. In this implementation, for example, the first width w1 of the depressed portion 321 may be less than or equal to half of the second width w2 of the opening 331.

Some light L2 directed laterally among light emitted from the emission layer 253 of the light emitting element 250 may be reflected from the second electrode 255 and caused to move outside of the display device 100. Therefore, the light extraction efficiency of the display device 100 can be improved. For example, since the depressed portion 321 of the first insulating layer 320 has the depression with a predefined depth d, an area of the second electrode 255 can increase by an area corresponding to the inclined portion 323 of the depressed portion 321. As the area of the second electrode 255 increases, among light emitted from the emission layer 253 of the light emitting element 250, an amount of some light L2 reflected from the second electrode 255 and caused to move outside of the display device 100 can increases. Therefore, the light extraction efficiency of the display device 100 can be improved.

Some light L1 directed laterally among light emitted from the emission layer 253 of the light emitting element 250 may be reflected from the second electrode 255 and caused to move outside of the display device 100, or pass through the color filter 211 and exit the display device 100. Therefore, light leakage in the display device 100 can be eliminated or reduced. In this way, since the depressed portion 321 of the first insulating layer 320 has the depression with a predefined depth d, and a depth at which the second electrode 255 is disposed increases by the depth d, light L1 emitted from the emission layer 253 of the light emitting element 250 can be prevented from directing laterally, and thereby, the light leakage defect of the display device 100 can be eliminated or reduced.

Referring to FIG. 4, each subpixel may include at least one light emitting area EA and a non-light emitting area NEA. The at least one light emitting area EA may include an area corresponding to the inclined portion 333 and the peripheral portion 334 of the opening 331. The at least one light emitting area EA may include a first light emitting area EA1 and a second light emitting area EA2. The first light emitting area EA1 may include an area overlapping with the first electrode 251 disposed in the peripheral portion 334 of the opening 331. The second light emitting area EA2 may include an area corresponding to the inclined portion 333 of the opening 331. The second light emitting area EA2 may include an area where light emitted from the emission layer 253 is reflected from the second electrode 255 disposed at the inclined portion 333 of the opening 331 and caused to move outside of the display device 100. The second light emitting area EA2 may further include an area not overlapping with the first electrode 251 disposed in the peripheral portion 334 of the opening 331. The second light emitting area EA2 may further include an area where light emitted from the emission layer 253 is reflected from the second electrode 255 disposed at the peripheral portion 334 of the opening 331 and caused to move outside of the display device 100. The non-light emitting area NEA may include an area corresponding to an area between light emitting areas EA. The non-light emitting area NEA may include an area corresponding to an area between the second light emitting areas EA2 or respective portions of the second light emitting area EA2.

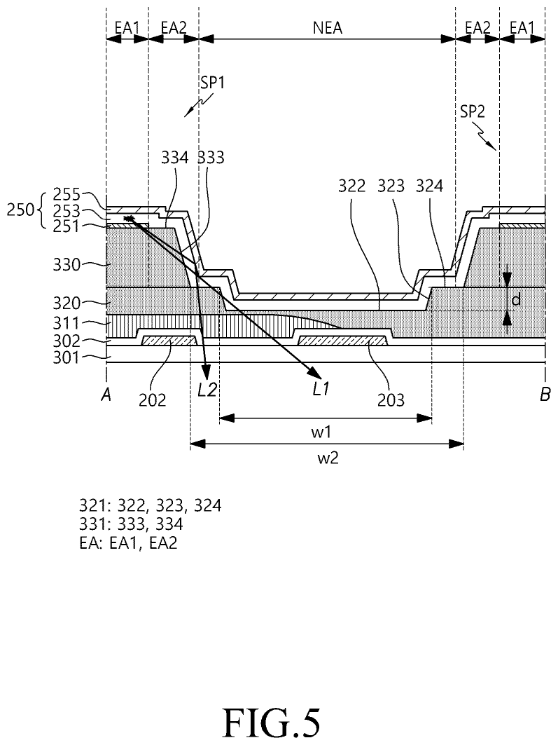

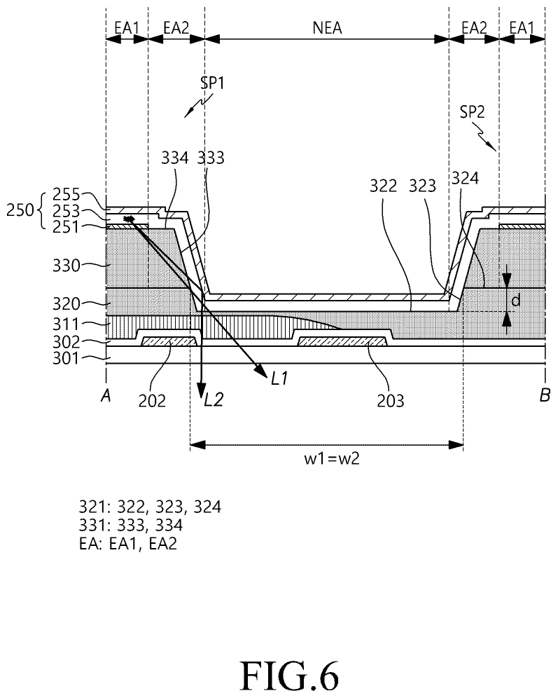

FIGS. 5 to 6 are other example cross-sectional views taken along line A-B of FIG. 3 according to embodiments of the present disclosure. In discussions that follow for the configurations of FIGS. 5 and 6, discussions for features and examples equal, substantially equal, or similar to the features and examples described with reference to FIGS. 1 to 4 are omitted or briefly described for convenience of description.

Referring to FIG. 5, for example, a first width w1, which is an upper width of a depression included in a depressed portion 321, may be greater than half of a second width w2, which is a lower width of an open portion included in an opening 331, and less than 1. In this implementation, an inclined portion 323 of the depressed portion 321 may be disposed adjacent to an inclined portion 323 of the opening 331.

As the inclined portion 323 of the depressed portion 321 is disposed adjacent to the inclined portion 323 of the opening 331, a second electrode 255 disposed on the inclined portion 323 of the depressed portion 321 may also be disposed adjacent to the inclined portion 323 of the opening 331. In this way, the second electrode 255 disposed on the inclined portion 323 of the depressed portion 321 may be disposed adjacent to a corresponding light emitting area. As the foregoing configurations are applied, among light emitted from an emission layer 253 of a light emitting element 250, an amount of some light L2 reflected from the second electrode 255 and caused to move outside of the display device 100 can increases. Therefore, the light extraction efficiency of the display device 100 can be improved. Further, some light L1 directed laterally among light emitted from the emission layer 253 of the light emitting element 250 may be reflected from the second electrode 255 disposed adjacent to the light emitting area and caused to move outside of the display device 100, or pass through a color filter 211 and exit the display device 100. Therefore, the light leakage defect of the display device 100 can be eliminated or reduced.

Referring to FIG. 5, each subpixel may include at least one light emitting area EA and a non-light emitting area NEA. The at least one light emitting area EA may include an area corresponding to the inclined portion 333 and a peripheral portion 334 of the opening 331. The at least one light emitting area EA may include a first light emitting area EA1 and a second light emitting area EA2. The first light emitting area EA1 may include an area overlapping with a first electrode 251 disposed in the peripheral portion 334 of the opening 331. The second light emitting area EA2 may include an area corresponding to the inclined portion 333 of the opening 331. The second light emitting area EA2 may further include an area that is non-overlapping with the first electrode 251 disposed in the peripheral portion 334 of the opening 331. The non-light emitting area NEA may include an area corresponding to an area between light emitting areas EA. The non-light emitting area NEA may include an area corresponding to an area between the second light emitting areas EA2 or respective portions of the second light emitting area EA2.

Referring to FIG. 5, the depressed portion 321 may be configured to overlap with one or more of the signal lines (201, 202, 203, and 204) or respective portions of one or more signal lines. The depressed portion 321 may be configured to overlap with respective portions of at least two signal lines, for example, the second and third signal lines (202 and 203). The depressed portion 321 including a flat portion 322, the inclined portion 323, and a peripheral portion 324 may be configured to partially overlap with at least one of the second and third signal lines (202 and 203). The flat portion 322 of the depressed portion 321 may be configured to partially overlap with at least one signal line, for example, the third signal line 203. The first width w1 of the depressed portion 321 may be greater than a width of the third signal line.

Referring to FIG. 6, for example, a first width w1, which is an upper width of a depression included in a depressed portion 321, may be equal to a second width w2, which is a lower width of an open portion included in an opening 331. In this implementation, an inclined portion 323 of the depressed portion 321 and an inclined portion 333 of the opening 331 may be disposed on a same inclined surface.

As the inclined portion 323 of the depressed portion 321 and the inclined portion 323 of the opening 331 are disposed on the same inclined surface, a second electrode 255 disposed on the inclined portion 323 of the depressed portion 321 may also be disposed on the same inclined surface as the second electrode 255 disposed on the inclined portion 323 of the opening 331. In this way, the second electrode 255 disposed on the inclined portion 323 of the depressed portion 321 may be disposed adjacent to a corresponding light emitting area. As the foregoing configurations are applied, among light emitted from an emission layer 253 of a light emitting element 250, an amount of some light L2 reflected from the second electrode 255 and caused to move outside of the display device 100 can increases. Therefore, the light extraction efficiency of the display device 100 can be improved. Further, some light L1 directed laterally among light emitted from the emission layer 253 of the light emitting element 250 may be reflected from the second electrode 255 disposed adjacent to the light emitting area and caused to move outside of the display device 100, or pass through a color filter 211 and exit the display device 100. Therefore, the light leakage defect of the display device 100 can be eliminated or reduced.

Referring to FIG. 6, each subpixel may include at least one light emitting area EA and a non-light emitting area NEA. The at least one light emitting area EA may include an area corresponding to the inclined portion 333 and a peripheral portion 334 of the opening 331, and an area corresponding to the inclined portion 323 of the depressed portion 321. The at least one light emitting area EA may include a first light emitting area EA1 and a second light emitting area EA2. The first light emitting area EA1 may include an area overlapping with the first electrode 251 disposed in the peripheral portion 334 of the opening 331. The second light emitting area EA2 may include an area corresponding to the inclined portion 333 of the opening 331. The second light emitting area EA2 may further include an area that is non-overlapping with the first electrode 251 disposed in the peripheral portion 334 of the opening 331. The second light emitting area EA2 may further include an area corresponding to the inclined portion 323 of the depressed portion 321. The non-light emitting area NEA may include an area corresponding to an area between light emitting areas EA. The non-light emitting area NEA may include an area corresponding to an area between the second light emitting areas EA2.

Referring to FIG. 6, the depressed portion 321 may be configured to overlap with one or more of the signal lines (201, 202, 203, and 204) or respective portions of one or more signal lines. The depressed portion 321 may be configured to overlap with respective portions of at least two signal lines, for example, the second and third signal lines (202 and 203). The depressed portion 321 including a flat portion 322, the inclined portion 323, and a peripheral portion 324 may be configured to partially overlap with at least one of the second and third signal lines (202 and 203). The flat portion 322 of the depressed portion 321 may be configured to overlap with at least one signal line, for example, the third signal line 203. The first width w1 of the depressed portion 321 may be greater than a width of the third signal line.

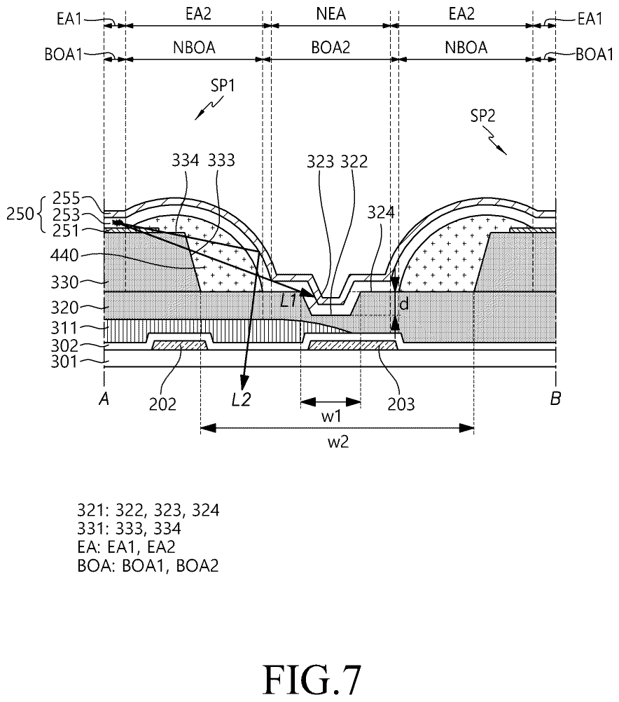

FIG. 7 is another example cross-sectional view taken along line A-B of FIG. 3 according to embodiments of the present disclosure. In discussions that follow for the configuration of FIG. 7, discussions for features and examples equal, substantially equal, or similar to the features and examples described with reference to FIGS. 1 to 6 are omitted or briefly described for convenience of description.

Referring to FIG. 7, a bank 440 may be disposed on a portion of a first insulating layer 320, a second insulating layer 330, and a first electrode 251.

Respective configurations of a substrate 301, second and third signal lines (202 and 203), a protective layer 302, a color filter 311, the first insulating layer 320, and the second insulating layer 330 illustrated in FIG. 7 may be substantially equal or similar to the configurations of corresponding elements illustrated in FIG. 4. Therefore, detailed discussions therefor are omitted for simplicity.

Referring to FIG. 7, a light emitting element 250 including the first electrode 251, an emission layer 253, and a second electrode 255 may be disposed on the second insulating layer 330.

The first electrode 251 may be disposed on the second insulating layer 330.

The first electrode 251 may be disposed on a peripheral portion 334 of the second insulating layer 330. The first electrode 251 may be disposed on the peripheral portion 334 of the second insulating layer 330 and disposed in an area parallel to any one surface of the substrate 301. The first electrode 251 may be disposed at a higher location from the substrate 301 than the depressed portion 321.

One end or edge of the first electrode 251 may have a regular taper shape, a reverse taper shape, or a vertical shape. In an example where the first electrode 251 is covered by the bank, the end or edge of the first electrode 251 may have a reverse taper shape.

The first electrode 251 may include a conductive material capable of transmitting or semi-transmitting light. For example, the first electrode 251 may include at least one type of transparent conductive oxide, such as indium tin oxide (ITO), indium zinc oxide (IZO), indium tin zinc oxide (ITZO), indium gallium zinc oxide (IGZO), zinc oxide, tin oxide, or the like, or may include a semi-transmissive metal, such as magnesium (Mg), silver (Ag), an alloy of magnesium and silver, or the like. For example, in an example where the first electrode 251 includes a semi-transmissive metal, a thickness of the first electrode 251 may be less than a thickness of the second electrode 255.

The bank 440 may be configured to cover at least a portion of the first electrode 251 and extend to a depressed portion 321. The bank 440 may be configured to cover at least the portion of the first electrode 251, and extend to an opening 331 of the second insulating layer 330 and the depressed portion 321 of the first insulating layer 320. For example, the bank 440 may be configured to cover at least the portion of the first electrode 251, and extend to the peripheral portion 334 and an inclined portion 333 of the opening 331, and a peripheral portion 324 of the depressed portion 321.

The emission layer 253 may be disposed on the first electrode 251 and the bank 440.

The emission layer 253 may be configured to extend from a portion of the emission layer 253 disposed on the first electrode 251 to the depressed portion 321. The emission layer 253 may be configured to extend from the portion of the emission layer 253 disposed on the first electrode 251 to the bank 440, and the peripheral portion 324, an inclined portion 323, and a flat portion 322 of the depressed portion 321. The emission layer 253 may be disposed commonly in subpixels (SP1, SP2, SP3, and SP4).

The second electrode 255 may be disposed on the emission layer 253.

The second electrode 255 may be configured to extend from a portion of the second electrode 255 disposed on the emission layer 253 to the depressed portion 321. The second electrode 255 may be configured to extend from the portion of the second electrode 255 disposed on the emission layer 253 to the bank 440, and the peripheral portion 324, the inclined portion 323, and the flat portion 322 of the depressed portion 321. The second electrode 255 may be disposed commonly in the subpixels (SP1, SP2, SP3, and SP4).

The second electrode 255 may include a conductive material capable of reflecting light. For example, the second electrode 255 may include either a metal such as aluminum (Al), magnesium (Mg), gold (Au), silver (Ag), copper (Cu), tungsten (W), molybdenum (Mo), chromium (Cr), tantalum (Ta), titanium (Ti), or the like, or any one of one or more alloys thereof, but aspects of the present disclosure are not limited thereto.

Some light L2 directed laterally among light emitted from the emission layer 253 of the light emitting element 250 may be reflected from the second electrode 255 and caused to move outside of the display device 100. Therefore, the light extraction efficiency of the display device 100 can be improved. For example, since the depressed portion 321 of the first insulating layer 320 has a depression with a predefined depth d, an area of the second electrode 255 can increase by an area corresponding to the inclined portion 323 of the depressed portion 321. As the area of the second electrode 255 increases, among light emitted from the emission layer 253 of the light emitting element 250, an amount of some light L2 reflected from the second electrode 255 and caused to move outside of the display device 100 can increases. Therefore, the light extraction efficiency of the display device 100 can be improved.

Some light L1 directed laterally among light emitted from the emission layer 253 of the light emitting element 250 may be reflected from the second electrode 255 and caused to move outside of the display device 100, or pass through the color filter 211 and exit the display device 100. Therefore, a light leakage defect of the display device 100 can be eliminated or reduced. In this way, since the depressed portion 321 of the first insulating layer 320 has the depression with a predefined depth d, and a depth at which the second electrode 255 is disposed increases by the depth d, light L1 emitted from the emission layer 253 of the light emitting element 250 can be prevented from directing laterally, and thereby, the light leakage defect of the display device 100 can be eliminated or reduced.

Referring to FIG. 7, the bank 440 may include an opened bank area BOA and a non-opened bank area NBOA. The opened bank area BOA may include a first opened bank area BOA1 corresponding to an area where a portion of the first electrode 251 is exposed, and a second opened bank area BOA2 corresponding to an area where the bank 440 and the depressed portion 331 do not overlap with each other. The non-opened bank area NBOA may include an area where the bank 440 is disposed.

Referring to FIG. 7, each subpixel may include at least one light emitting area EA and a non-light emitting area NEA. The at least one light emitting area EA may include an area corresponding to a first opened bank area BOA1 and a non-opened bank area NBOA. The non-light emitting area NEA may include an area corresponding to the second opened bank area BOA2.

Referring to FIG. 7, the at least one light emitting area EA may include a first light emitting area EA1 corresponding to the first opened bank area BOA1, and a second light emitting area EA2 corresponding to the non-opened bank area NBOA. The first light emitting area EA1 may include an area overlapping with the first electrode 251 disposed in the peripheral portion 334 of the opening 331. The second light emitting area EA2 may include an area where light emitted from the emission layer 253 is reflected from the second electrode 255 disposed on the bank 440 and caused to move outside of the display device 100.

Referring to FIG. 7, a depression included in the depressed portion 331 may have a first width w1, which is an upper width of the depression. The first width w1 may be smaller than a width of the second opened bank area BOA2.

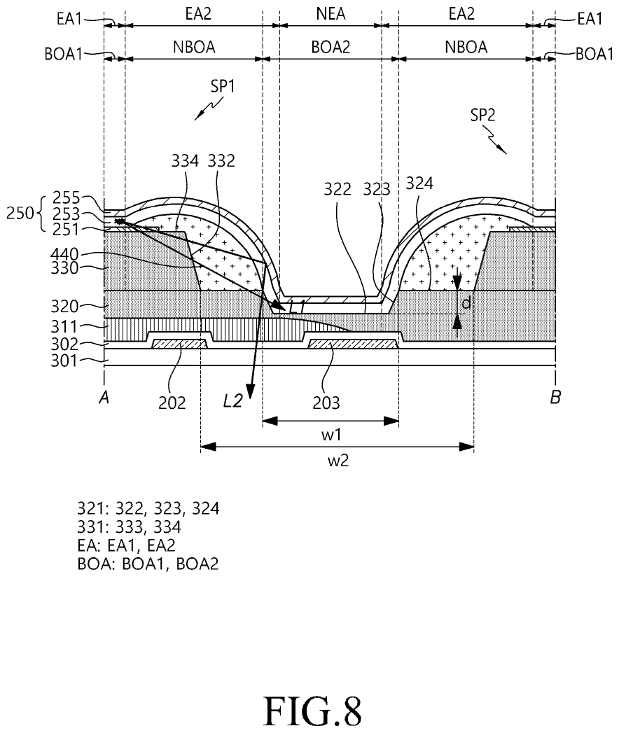

FIG. 8 is another example cross-sectional view taken along line A-B of FIG. 3 according to embodiments of the present disclosure. In discussions that follow for the configuration of FIG. 8, discussions for features and examples equal, substantially equal, or similar to the features and examples described with reference to FIGS. 1 to 7 are omitted or briefly described for convenience of description.

Referring to FIG. 8, a bank 440 may be disposed on a portion of a first insulating layer 320, a second insulating layer 330, and a first electrode 251.

Respective configurations of a substrate 301, second and third signal lines (202 and 203), a protective layer 302, a color filter 311, the first insulating layer 320, and the second insulating layer 330 illustrated in FIG. 8 may be substantially equal or similar to the configurations of corresponding elements illustrated in FIG. 4. Therefore, detailed discussions therefor are omitted for simplicity.

The bank 440 may be configured to cover at least a portion of the first electrode 251 and extend to a depressed portion 321. The bank 440 may be configured to cover at least the portion of the first electrode 251, and extend to an opening 331 of the second insulating layer 330 and the depressed portion 321 of the first insulating layer 320. For example, the bank 440 may be configured to cover at least the portion of the first electrode 251, and extend to a peripheral portion 334 and an inclined portion 333 of the opening 331 and a boundary between a peripheral portion 324 and an inclined portion 323 of the depressed portion 321.

Some light L2 directed laterally among light emitted from an emission layer 253 of a light emitting element 250 may be reflected from a second electrode 255 and caused to move outside of the display device 100. Therefore, the light extraction efficiency of the display device 100 can be improved. For example, since the depressed portion 321 of the first insulating layer 320 has a depression with a predefined depth d, an area of the second electrode 255 can increase by an area corresponding to the inclined portion 323 of the depressed portion 321. As the area of the second electrode 255 increases, among light emitted from the emission layer 253 of the light emitting element 250, an amount of some light L2 reflected from the second electrode 255 and caused to move outside of the display device 100 can increases. Therefore, the light extraction efficiency of the display device 100 can be improved.

Some light L1 directed laterally among light emitted from the emission layer 253 of the light emitting element 250 may be reflected from the second electrode 255 and caused to move outside of the display device 100, or pass through the color filter 211 and exit the display device 100. Therefore, a light leakage defect of the display device 100 can be eliminated or reduced. In this way, since the depressed portion 321 of the first insulating layer 320 has the depression with a predefined depth d, and a depth at which the second electrode 255 is disposed increases by the depth d, light L1 emitted from the emission layer 253 of the light emitting element 250 can be prevented from directing laterally, and thereby, the light leakage defect of the display device 100 can be eliminated or reduced.

Referring to FIG. 8, the bank 440 may include an opened bank area BOA and a non-opened bank area NBOA. The opened bank area BOA may include a first opened bank area BOA1 corresponding to an area where a portion of the first electrode 251 is exposed, and a second opened bank area BOA2 corresponding to an area where the bank 440 and the depressed portion 331 do not overlap with each other. The non-opened bank area BNOA may include an area where the bank 440 is disposed.

Referring to FIG. 8, each subpixel may include at least one light emitting area EA and a non-light emitting area NEA. The at least one light emitting areas EA may include an area corresponding to a first opened bank area BOA1 and a non-opened bank area NBOA. The non-light emitting area NEA may include an area corresponding to the second opened bank area BOA2.

Referring to FIG. 8, the at least one light emitting area EA may include a first light emitting area EA1 corresponding to the first opened bank area BOA1, and a second light emitting area EA2 corresponding to the non-opened bank area NBOA. The first light emitting area EA1 may include an area overlapping with the first electrode 251 disposed in the peripheral portion 334 of the opening 331. The second light emitting area EA2 may include an area where light emitted from the emission layer 253 is reflected from the second electrode 255 disposed on the bank 440 and caused to move outside of the display device 100.

Referring to FIG. 8, a depression included in the depressed portion 331 may have a first width w1, which is an upper width of the depression. The first width w1 may be equal to a width of the second opened bank area BOA2.

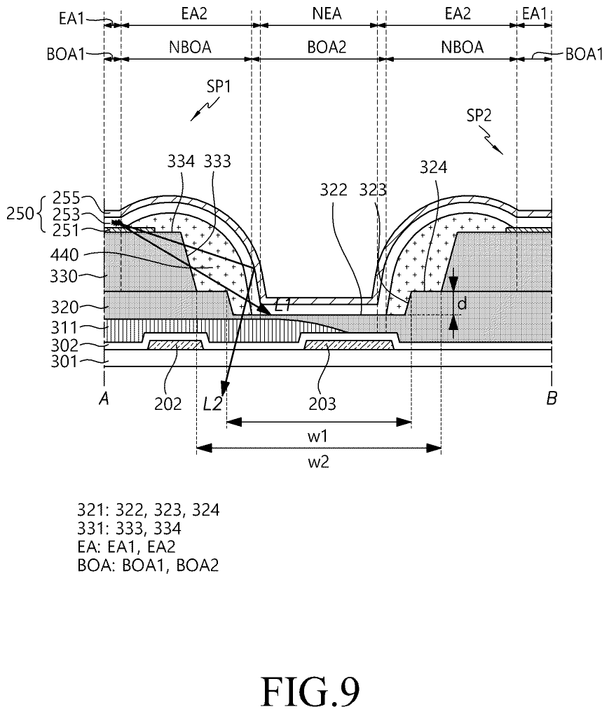

FIG. 9 is another example cross-sectional view taken along line A-B of FIG. 3 according to embodiments of the present disclosure. In discussions that follow for the configuration of FIG. 9, discussions for features and examples equal, substantially equal, or similar to the features and examples described with reference to FIGS. 1 to 8 are omitted or briefly described for convenience of description.

Referring to FIG. 9, a bank 440 may be disposed on a first insulating layer 320, a second insulating layer 330, and a portion of a first electrode 251.

Respective configurations of a substrate 301, second and third signal lines (202 and 203), a protective layer 302, a color filter 311, the first insulating layer 320, and the second insulating layer 330 illustrated in FIG. 9 may be substantially equal or similar to the configurations of corresponding elements illustrated in FIG. 5. Therefore, detailed discussions therefor are omitted for simplicity.

The bank 440 may be configured to cover at least a portion of the first electrode 251 and extend to a depressed portion 321. The bank 440 may be configured to cover at least the portion of the first electrode 251 and extend to an opening 331 of the second insulating layer 330 and the depressed portion 321 of the first insulating layer 320. For example, the bank 440 may be configured to cover at least the portion of the first electrode 251, and extend to a peripheral portion 334 and an inclined portion 333 of the opening 331, and a peripheral portion 324, an inclined portion 323, and a flat portion of the depressed portion 321.

As the inclined portion 323 of the depressed portion 321 is disposed adjacent to the inclined portion 323 of the opening 331, a second electrode 255 disposed on the bank 440 may be disposed adjacent to a light emitting area. As the foregoing configurations are applied, among light emitted from an emission layer 253 of the light emitting element 250, an amount of some light reflected from the second electrode 255 and caused to move outside of the display device 100 can increases. Therefore, the light extraction efficiency of the display device 100 can be improved. Further, some light L1 directed laterally among light emitted from the emission layer 253 of the light emitting element 250 may be reflected from the second electrode 255 disposed adjacent to the light emitting area and caused to move outside of the display device 100, or pass through the color filter 211 and exit the display device 100. Therefore, the light leakage defect of the display device 100 can be eliminated or reduced.

Referring to FIG. 9, the bank 440 may include an opened bank area BOA and a non-opened bank area NBOA. The opened bank area BOA may include a first opened bank area BOA1 corresponding to an area where a portion of the first electrode 251 is exposed, and a second opened bank area BOA2 corresponding to an area where the bank 440 and the depressed portion 331 do not overlap with each other. The non-opened bank area BNOA may include an area where the bank 440 is disposed.

Referring to FIG. 9, each subpixel may include at least one light emitting area EA and a non-light emitting area NEA. The at least one light emitting area EA may include an area corresponding to a first opened bank area BOA1 and a non-opened bank area NBOA. The non-light emitting area NEA may include an area corresponding to the second opened bank area BOA2.

Referring to FIG. 9, the at least one light emitting area EA may include a first light emitting area EA1 corresponding to the first opened bank area BOA1, and a second light emitting area EA2 corresponding to the non-opened bank area BNOA. The first light emitting area EA1 may include an area overlapping with the first electrode 251 disposed in the peripheral portion 334 of the opening 331. The second light emitting area EA2 may include an area where light emitted from the emission layer 253 is reflected from the second electrode 255 disposed on the bank 440 and caused to move outside of the display device 100.

Referring to FIG. 9, a depression included in the depressed portion 331 may have a first width w1, which is an upper width of the depression. The first width w1 may be greater than a width of the second opened bank area BOA2.

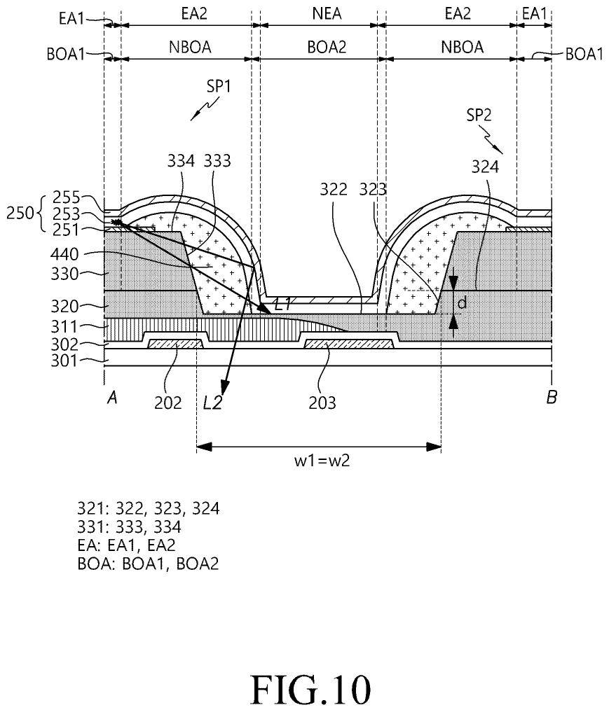

FIG. 10 is another example cross-sectional view taken along line A-B of FIG. 3 according to embodiments of the present disclosure. In discussions that follow for the configuration of FIG. 10, discussions for features and examples equal, substantially equal, or similar to the features and examples described with reference to FIGS. 1 to 9 are omitted or briefly described for convenience of description.

Referring to FIG. 10, a bank 440 may be disposed on a portion of a first insulating layer 320, a second insulating layer 330, and a first electrode 251.

Respective configurations of a substrate 301, second and third signal lines (202 and 203), a protective layer 302, a color filter 311, the first insulating layer 320, and the second insulating layer 330 illustrated in FIG. 10 may be substantially equal or similar to the configurations of corresponding elements illustrated in FIG. 6. Therefore, detailed discussions therefor are omitted for simplicity.

The bank 440 may be configured to cover at least a portion of the first electrode 251 and extend to a depressed portion 321. The bank 440 may be configured to cover at least the portion of the first electrode 251 and extend to an opening 331 of the second insulating layer 330 and the depressed portion 321 of the first insulating layer 320. For example, the bank 440 may be configured to cover at least the portion of the first electrode 251, and extend to a peripheral portion 334 and an inclined portion 333 of the opening 331, and an inclined portion 323 and a flat portion of the depressed portion 321.

As the inclined portion 323 of the depressed portion 321 and the inclined portion 323 of the opening 331 are disposed on a same inclined surface, a second electrode 255 disposed on the bank 440 may be disposed adjacent to a light emitting area. As the foregoing configurations are applied, among light emitted from an emission layer 253 of the light emitting element 250, an amount of some light reflected from the second electrode 255 and caused to move outside of the display device 100 can increases. Therefore, the light extraction efficiency of the display device 100 can be improved. Further, some light L1 directed laterally among light emitted from the emission layer 253 of the light emitting element 250 may be reflected from the second electrode 255 disposed adjacent to the light emitting area and caused to move outside of the display device 100, or pass through the color filter 211 and exit the display device 100. Therefore, the light leakage defect of the display device 100 can be eliminated or reduced.

Referring to FIG. 10, the bank 440 may include an opened bank area BOA and a non-opened bank area NBOA. The opened bank area BOA may include a first opened bank area BOA1 corresponding to an area where a portion of the first electrode 251 is exposed, and a second opened bank area BOA2 corresponding to an area where the bank 440 and the depressed portion 331 do not overlap with each other. The non-opened bank area NBOA may include an area where the bank 440 is disposed.

Referring to FIG. 10, each subpixel may include at least one light emitting area EA and a non-light emitting area NEA. The at least one light emitting area EA may include an area corresponding to a first opened bank area BOA1 and a non-opened bank area NBOA. The non-light emitting area NEA may include an area corresponding to the second opened bank area BOA2.

Referring to FIG. 10, the at least one light emitting area EA may include a first light emitting area EA1 corresponding to the first opened bank area BOA1, and a second light emitting area EA2 corresponding to the non-opened bank area BNOA. The first light emitting area EA1 may include an area overlapping with the first electrode 251 disposed in the peripheral portion 334 of the opening 331. The second light emitting area EA2 may include an area where light emitted from the emission layer 253 is reflected from the second electrode 255 disposed on the bank 440 and caused to move outside of the display device 100.

Referring to FIG. 10, a depression included in the depressed portion 331 may have a first width w1, which is an upper width of the depression. The first width w1 may be greater than a width of the second opened bank area BOA2. The inclined portion 323 of the depressed portion 321 and the inclined portion 333 of the opening 331 may be disposed on a same inclined surface.

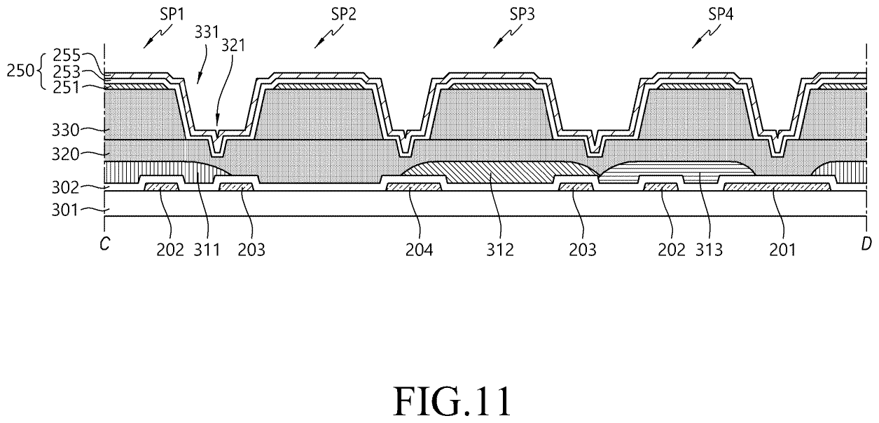

FIG. 11 is an example cross-sectional view taken along line C-D of FIG. 3 according to embodiments of the present disclosure. In discussions that follow for the configuration of FIG. 11, discussions for features and examples equal, substantially equal, or similar to the features and examples described with reference to FIGS. 1 to 10 are omitted or briefly described for convenience of description.

Referring to FIG. 11, in one or more embodiments, the display device 100 may include a substrate 301, the plurality of subpixels (SP1 SP2, SP3, SP4) disposed on the substrate 301, a first insulating layer 320 including at least one depressed portion 321, a second insulating layer 330 including at least one opening 331, and at least one light emitting element 250.

Referring to FIG. 11, the plurality of signal lines (201, 202, 203, 204) may be disposed on the substrate 301. A protective layer 302 may be disposed on the plurality of signal lines (201, 202, 203, 204) and the substrate 301.

Referring to FIG. 11, each of all or some of first to fourth subpixels (SP1, SP2, SP3, and SP4) may include a color filter (311, 312, or 313) corresponding to a color of light emitted from a corresponding subpixel.

For example, a red (R) color filter 311 may be disposed in the area of the first subpixel SP1 including a light emitting area emitting red (R) light, a blue (B) color filter 312 may be disposed in the area of the third subpixel SP3 including a light emitting area emitting blue (B) light, and a green (G) color filter 313 may be disposed in the area of the fourth subpixel SP4 including the light emitting area emitting green (G) light.

A separate color filter may be not disposed in the area of the second subpixel SP2 including a light emitting area emitting white (W) light. For example, an insulating layer may be disposed in the area of the second subpixel SP2 including the light emitting area emitting white (W) light. For example, the first insulating layer 320, the second insulating layer 330, and the protective layer 302, and the like disposed or stacked in the area of the second subpixel SP2 may include a transparent material, and therefore, a separate color filter may be not disposed in the area of the second subpixel SP2.

Referring to FIG. 11, in one or more embodiments, the first insulating layer 320 may include depressed portions 321 disposed between adjacent subpixels among the first to fourth subpixels (SP1, SP2, SP3, and SP4).

For example, the first insulating layer 320 may include depressed portions 321 disposed between the first subpixel SP1 and the second subpixel SP2, between the second subpixel SP2 and the third subpixel SP3, between the third subpixel SP3 and the fourth subpixel SP4, and between the fourth subpixel SP4 and the first subpixel SP1, respectively. In one or more aspects, each depressed portion 321 may be disposed in a non-light emitting area between adjacent subpixels. The depressed portion 321 may be defined as an area including an area where a portion of the first insulating layer 320 is removed and a surrounding area. The depressed portion 321 may include a flat portion, an inclined portion surrounding the flat portion, and a peripheral portion extending from the inclined portion.

Referring to FIG. 11, in one or more embodiments, the second insulating layer 330 may include openings 331 disposed between adjacent subpixels among the first to fourth subpixels (SP1, SP2, SP3, and SP4).

For example, the second insulating layer 330 may include openings 331 disposed between the first subpixel SP1 and the second subpixel SP2, between the second subpixel SP2 and the third subpixel SP3, between the third subpixel SP3 and the fourth subpixel SP4, and between the fourth subpixel SP4 and the first subpixel SP1, respectively. Each of the openings 331 of the second insulating layer 330 may be disposed on the peripheral portion of the first insulating layer 320 to be located in an area corresponding to an area where each of the depressed portions 321 of the first insulating layer 320 is disposed. The opening 331 may be defined as an area including an area where a portion of the second insulating layer 330 is removed and a surrounding area. For example, the opening 331 may include an inclined portion and a peripheral portion extending from the inclined portion.

Referring to FIG. 11, a light emitting element 250 including a first electrode 251, an emission layer 253, and a second electrode 255 may be disposed on the second insulating layer 330.

The first electrode 251 may be disposed on the peripheral portion of the second insulating layer 330. The first electrode 251 may be disposed on the peripheral portion of the second insulating layer 330 and disposed in an area parallel to any one surface of the substrate 301. The first electrode 251 may be disposed at a higher location from the substrate 301 than the depressed portion 321. The first electrode 251 may include a light-transmissive conductive material or a semi-light-transmissive conductive material. The first electrode 251 may have a tapered end.

The emission layer 253 and the second electrode 255 may be configured to be sequentially stacked on the first electrode 251. The emission layer 253 and the second electrode 255 may be configured to extend from respective portions of the emission layer 253 and the second electrode 255 disposed on the first electrode 251 to the depressed portion 321. The emission layer 253 and the second electrode 255 may be configured to extend from the respective portions of the emission layer 253 and the second electrode 255 disposed on the first electrode 251 to the peripheral portion and the inclined portion of the opening 331, and the peripheral portion, the inclined portion, and the flat portion of the depressed portion 321. The emission layer 253 and the second electrode 255 may be disposed commonly in the subpixels (SP1, SP2, SP3, SP4). The second electrode 255 may include a light-reflective conductive material.

Referring to FIG. 11, the depressed portion 321 of the first insulating layer 320 and the opening 331 of the second insulating layer 330 may be configured to overlap with each other, and the light emitting element 250 may be located at a higher location from the substrate 301 than the depressed portion 321. In one or more aspects, the second electrode 255 including a light-reflective conductive material may be disposed even on the flat surface of the depressed portion 321. By applying the configurations discussed above, light emitted from the emission layer 253 of the light emitting element 250 can be reflected from the second electrode 255 and caused to move outside of the display device 100. Thereby, the light extraction efficiency of the display device 100 can be improved, some light can be prevented from being directed to an adjacent subpixel, and the light leakage defect of the display device 100 can be eliminated or reduced.

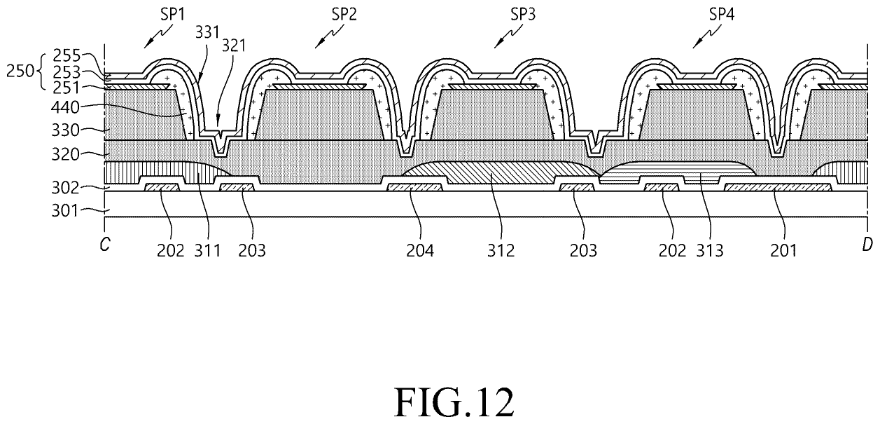

FIG. 12 is an example cross-sectional view taken along line C-D of FIG. 3 according to embodiments of the present disclosure. In discussions that follow for the configuration of FIG. 12, discussions for features and examples equal, substantially equal, or similar to the features and examples described with reference to FIGS. 1 to 11 are omitted or briefly described for convenience of description.

Referring to FIG. 12, in one or more embodiments, the display device 100 may include the plurality of subpixels (SP1 SP2, SP3, SP4) disposed on a substrate 301, a first insulating layer 320 including at least one depressed portion 321, a second insulating layer 330 including at least one opening 331, a light emitting element 250, and a bank 440 disposed on a portion of the first electrode 251.

Respective configurations of the substrate 301, the plurality of subpixels (SP1 SP2, SP3, SP4), a protective layer 302, one or more color filters (311, 312, 311), the first insulating layer 320, and the second insulating layer 330 illustrated in FIG. 12 may be substantially equal or similar to the configurations of corresponding elements illustrated in FIG. 11. Therefore, detailed discussions therefor are omitted for simplicity.

Referring to FIG. 12, a light emitting element 250 including a first electrode 251, an emission layer 253, and a second electrode 255 may be disposed on the second insulating layer 330.

The first electrode 251 may be disposed on a peripheral portion of the second insulating layer 330. The first electrode 251 may be disposed on the peripheral portion of the second insulating layer 330 and disposed in an area parallel to any one surface of the substrate 301. The first electrode 251 may be disposed at a higher location from the substrate 301 than the depressed portion 321. The first electrode 251 may include a light-transmissive conductive material or a semi-light-transmissive conductive material. The first electrode 251 may have a reverse tapered end.

Referring to FIG. 12, the bank 440 may be disposed on a portion of the first electrode 251. The bank 440 may be configured to cover at least a portion of the first electrode 251 and extend to the depressed portion 321. The bank 440 may be configured to cover at least the portion of the first electrode 251 and extend to the opening 331 of the second insulating layer 330 and the depressed portion 321 of the first insulating layer 320.

The emission layer 253 and the second electrode 255 may be configured to be sequentially stacked on the first electrode 251 and the bank 440. The emission layer 253 and the second electrode 255 may be configured to extend from respective portions of the emission layer 253 and the second electrode 255 disposed on the first electrode 251 to the bank 440 and the depressed portion 321. The emission layer 253 and the second electrode 255 may be configured to extend from the respective portions of the emission layer 253 and the second electrode 255 disposed on the first electrode 251 to the bank 440, a peripheral portion and an inclined portion of the opening 331, and a peripheral portion, an inclined portion, and a flat portion of the depressed portion 321. The emission layer 253 and the second electrode 255 may be disposed commonly in the subpixels (SP1, SP2, SP3, SP4). The second electrode 255 may include a light-reflective conductive material.

Referring to FIG. 12, the depressed portion 321 of the first insulating layer 320 and the opening 331 of the second insulating layer 330 may be configured to overlap with each other, and the light emitting element 250 may be located at a higher location from the substrate 301 than the depressed portion 321. In one or more embodiments, the second electrode 255 including a light-reflective conductive material may be disposed even on the bank 440 and the flat portion of the depressed portion 321. By applying the configurations discussed above, light emitted from the emission layer 253 of the light emitting element 250 can be reflected from the second electrode 255 and caused to move outside of the display device 100. Thereby, the light extraction efficiency of the display device 100 can be improved, some light can be prevented from being directed to an adjacent subpixel, and the light leakage defect of the display device 100 can be eliminated or reduced.

The example embodiments described above will be briefly described as follows.

According to the example embodiments described herein, a display device can be provided that includes a substrate on which a plurality of subpixels are disposed, a first insulating layer disposed over the substrate and including at least one depressed portion between the plurality of subpixels, a second insulating layer disposed on the first insulating layer and including at least one opening corresponding to the at least one depressed portion, and a first electrode disposed on the second insulating layer.

In one or more embodiments, the depressed portion may include a flat portion, an inclined portion extending from the flat portion, and a peripheral portion extending from the inclined portion, and the opening may include an inclined portion and a peripheral portion extending from the inclined portion.

In one or more embodiments, the depressed portion may have a first width that is an upper width of a depression included in the depressed portion, and the opening may have a second width that is a lower width of an open portion included in the opening. For example, the first width may be smaller than or equal to the second width.

For example, the first width may be less than half of the second width.

For example, the first width may be greater than half of the second width and less than the second width.

For example, the first width may be equal to the second width.

In one or more embodiments, each of the subpixels may include at least one light emitting area and a non-light emitting area. For example, the at least one light emitting area may be an area corresponding to the inclined portion and the peripheral portion of the opening, and the non-light emitting area may correspond to an area between adjacent light emitting areas among the at least one light emitting area.

In one or more embodiments, the at least one light emitting area may include a first light emitting area and a second light emitting area. For example, the first light emitting area may correspond to an area overlapping with the first electrode disposed at the peripheral portion of the opening, and the second light emitting area may be an area corresponding to the inclined portion of the opening.

In one or more embodiments, the second light emitting area may further include an area not overlapping with the first electrode disposed at the peripheral portion of the opening.

In one or more embodiments, the second light emitting area may further include an area corresponding to the inclined portion of the depressed portion.

In one or more aspects, the first electrode may have a tapered shape.

In one or more embodiments, the display device may further include an emission layer disposed on the first electrode, and a second electrode disposed on the emission layer.

In one or more embodiments, the emission layer and the second electrode may be configured to extend from respective portions of the emission layer and the second electrode on the first electrode to the depressed portion.

In one or more embodiments, the first electrode may be disposed at a location higher from the substrate than the depressed portion.

In one or more embodiments, the display device may further include at least one signal line disposed on the substrate and partially overlapping with the depressed portion.

In one or more embodiments, the at least one signal line may include at least one signal line disposed in an area overlapping with the flat portion of the depressed portion.

In one or more embodiments, the at least one signal line may include at least two signal lines disposed in an area overlapping with the flat portion of the depressed portion.

In one or more embodiments, the depressed portion may have a first width that is an upper width of a depression included in the depressed portion, and the first width may be smaller than a width of the at least one signal line.

In one or more embodiments, the depressed portion may have a first width that is an upper width of a depression included in the depressed portion, and the first width may be greater than a width of the at least one signal line.

In one or more embodiments, the display device may further include a color filter layer disposed over the substrate and configured to partially overlap with the at least one signal line.

In one or more embodiments, the first insulating layer may be disposed between the color filter layer and the depressed portion.

In one or more embodiments, the display device may further include a bank configured to cover at least a portion of the first electrode and extend to the depressed portion.

In one or more embodiments, the inclined portion of the opening may be disposed on the peripheral portion of the depressed portion.

In one or more embodiments, the bank may be configured to extend to the peripheral portion of the depressed portion.

In one or more embodiments, the bank may be configured to extend to a boundary between the peripheral portion and the inclined portion of the depressed portion.

In one or more embodiments, the bank may be configured to extend to the flat portion of the depressed portion.

In one or more embodiments, the inclined portion of the depressed portion and the inclined portion of the opening may be located on a same inclined surface, and the bank may be configured to extend to the flat portion of the depressed portion.

In one or more embodiments, the bank may include a first opened bank area corresponding to an area where a portion of the first electrode is exposed, a second opened bank area corresponding to an area where the bank and the depressed portion do not overlap with each other, and a non-opened bank area where the bank is disposed.

In one or more embodiments, each of the subpixels may include at least one light emitting area and a non-light emitting area. For example, the at least one light emitting area may be an area corresponding to the first opened bank area and the non-opened bank area, and the non-light emitting area may be an area corresponding to the second opened bank area.

In one or more embodiments, the light emitting area may include a first light emitting area corresponding to the first opened bank area, and a second light emitting area corresponding to the non-opened bank area.

In one or more embodiments, the depressed portion may have a first width that is an upper width of a depression included in the depressed portion, and the first width may be smaller than a width of the second opened bank area.

In one or more embodiments, the inclined portion of the depressed portion and the inclined portion of the opening may be disposed on a same inclined surface.

In one or more embodiments, the depressed portion may have a first width that is an upper width of a depression included in the depressed portion, and the first width may be equal to a width of the second opened bank area.

In one or more embodiments, the depressed portion may have a first width that is an upper width of a depression included in the depressed portion, and the first width may be greater than a width of the second opened bank area.

In one or more embodiments, the first electrode may have a reverse tapered shape.

According to the example embodiments described herein, a display device can be provided that includes a substrate, a first insulating layer disposed over the substrate, and including a depressed portion including a flat portion, an inclined portion extending from the flat portion, and a peripheral portion extending from the inclined portion, a second insulating layer disposed on the first insulating layer and disposed in an area corresponding to the peripheral portion of the depressed portion, a first electrode disposed on the second insulating layer, an emission layer disposed on the first electrode and disposed on the depressed portion, and a second electrode disposed on the emission layer.

In one or more embodiments, the display device may further include a bank configured to cover at least a portion of the first electrode and extend to the depressed portion.

According to the one or more embodiments described herein, a display device may be provided that includes structures where a depressed portion and an opening are disposed between subpixels, and thereby, is capable of improving light extraction efficiency.

According to the one or more embodiments described herein, a display device may be provided that includes structures where a depressed portion and an opening are disposed between subpixels, and thereby, is capable of eliminating or reducing light leakage between subpixels.

According to the one or more embodiments described herein, a display device may be provided that is capable of improving image quality by improving light extraction efficiency and eliminating or reducing light leakage between subpixels.

According to the one or more embodiments described herein, a display device may be provided that is capable of being driven with low power by improving light extraction efficiency and eliminating or reducing light leakage between subpixels.

The above description has been presented to enable any person skilled in the art to make, use and practice the technical features of the present invention, and has been provided in the context of a particular application and its requirements as examples. Various modifications, additions and substitutions to the described embodiments will be readily apparent to those skilled in the art, and the principles described herein may be applied to other embodiments and applications without departing from the scope of the present invention. The above description and the accompanying drawings provide examples of the technical features of the present invention for illustrative purposes only. That is, the disclosed embodiments are intended to illustrate the scope of the technical features of the present invention.

What is claimed is:

1. A display device comprising:
a substrate on which a plurality of subpixels are disposed;
a first insulating layer over the substrate, the first insulating layer comprising at least one depressed portion between the plurality of subpixels;
a second insulating layer on the first insulating layer, the second insulating layer comprising at least one opening corresponding to the at least one depressed portion; and
a first electrode on the second insulating layer.

2. The display device of claim 1, wherein the at least one depressed portion comprises a flat portion, an inclined portion extending from the flat portion, and a peripheral portion extending from the inclined portion, and the at least one opening comprises an inclined portion and a peripheral portion extending from the inclined portion of the at least one opening.

3. The display device of claim 2, wherein the at least one depressed portion has a first width that is an upper width of a depression included in the at least one depressed portion, and the at least one opening has a second width that is a lower width of an open portion included in the at least one opening, and
wherein the first width is smaller than or equal to the second width.

4. The display device of claim 3, wherein the first width is less than or equal to half of the second width,
the first width is greater than half of the second width and less than the second width, or
the first width is equal to the second width.

5. The display device of claim 2, wherein each of the plurality of subpixels comprises at least one light emitting area and a non-light emitting area, and
wherein the at least one light emitting area is an area corresponding to the inclined portion and the peripheral portion of the at least one opening, and the non-light emitting area corresponds to an area between adjacent light emitting areas among the at least one light emitting area.

6. The display device of claim 5, wherein the at least one light emitting area comprises a first light emitting area and a second light emitting area, and
wherein the first light emitting area corresponds to an area overlapping with the first electrode disposed at the peripheral portion of the at least one opening, and the second light emitting area is an area corresponding to the inclined portion of the at least one opening.

7. The display device of claim 6, wherein the second light emitting area further comprises an area that is non-overlapping with the first electrode disposed at the peripheral portion of the at least one opening.

8. The display device of claim 6, wherein the second light emitting area further comprises an area corresponding to the inclined portion of the at least one depressed portion.

9. The display device of claim 1, wherein the first electrode has a tapered shape or a reverse tapered shape.

10. The display device of claim 1, further comprising:
an emission layer on the first electrode; and
a second electrode on the emission layer,
wherein the emission layer and the second electrode are configured to extend from respective portions of the emission layer and the second electrode on the first electrode to the at least one depressed portion.

11. The display device of claim 1, wherein the first electrode is at a location that is higher from the substrate than the at least one depressed portion.

12. The display device of claim 1, further comprising:
at least one signal line on the substrate and partially overlapping with the at least one depressed portion.

13. The display device of claim 12, wherein the at least one signal line comprises at least one signal line or at least two signal lines in an area overlapping with a flat portion of the at least one depressed portion.

14. The display device of claim 12, wherein the at least one depressed portion has a first width that is an upper width of a depression included in the at least one depressed portion, and the first width is smaller or greater than a width of the at least one signal line.

15. The display device of claim 12, further comprising:
a color filter layer over the substrate and partially overlapping with the at least one signal line.

16. The display device of claim 2, further comprising:
a bank covering at least a portion of the first electrode and extending to the at least one depressed portion.

17. The display device of claim 16, wherein the inclined portion of the at least one opening is on the peripheral portion of the at least one depressed portion.

18. The display device of claim 17, wherein the bank extends to the peripheral portion of the at least one depressed portion, a boundary between the peripheral portion and the inclined portion of the at least one depressed portion or the flat portion of the at least one depressed portion.

19. The display device of claim 16, wherein the inclined portion of the at least one depressed portion and the inclined portion of the at least one opening are on a same inclined surface, and the bank extends to the flat portion of the at least one depressed portion.

20. A display device comprising:
a substrate;
a first insulating layer over the substrate, the first insulating layer comprising a depressed portion comprising a flat portion, an inclined portion extending from the flat portion, and a peripheral portion extending from the inclined portion;
a second insulating layer on the first insulating layer and in an area corresponding to the peripheral portion of the depressed portion;
a first electrode on the second insulating layer;
an emission layer on the first electrode and on the depressed portion; and
a second electrode on the emission layer.
